(19) United States
(12) Patent Application Publication
(10) Pub. No.: US 2026/0205117 A1
(43) Pub. Date: Jul. 16, 2026

(54) BODY-REGISTERING UNIFIED CIRCUIT IN-LINE TOUCH SWITCH

(71) Applicant: Banner Engineering Corp., Minneapolis, MN (US)

(72) Inventors: Charles Dolezalek, Blaine, MN (US); Matthew Munn, Minneapolis, MN (US); William Theunissen, Minneapolis, MN (US)

(73) Assignee: Banner Engineering Corp., Minneapolis, MN (US)

(21) Appl. No.: 19/135,674

(22) PCT Filed: Feb. 6, 2024
(86) PCT No.: PCT/US2024/014620

§ 371 Date: Jun. 4, 2025

Related U.S. Application Data
(60) Provisional application No. 63/483,476, filed on Feb. 6, 2023.

(51) Int. Cl. H03K 17/96; G06F 3/041; G06F 3/044

(52) U.S. Cl. CPC H03K 17/962; G06F 3/0416; G06F 3/044

(57) ABSTRACT

Apparatus and associated methods relate to an inline capacitive touch switch (ICTS) with an ergonomic design to register with a body portion. In an illustrative example, the ICTS may include a single inline circuit board (SICB) extending in a horizontal axis, serially and operably connecting an input port and an output port. The SICB, for example, may include a capacitive touch input electrode directly disposed on a gap of the SICB. The ICTS may, for example, further include a housing enclosing the SICB entirely. For example, the housing may include at least one saddle depression. For example, each of the at least one saddle depression may, for example, be registered with the corresponding capacitive touch-input electrode. Various embodiments may advantageously provide a visually apparent touch area for the user to operably engage with the at least one capacitive touch input electrode through the housing.

### CROSS-REFERENCE TO RELATED APPLICATIONS

This application claims the benefit of U.S. Provisional Application Ser. No. 63/483,476, titled “Body-Registering Unified Circuit In-Line Touch Switch,” filed by Charles Dolezalek, et al., on Feb. 6, 2023.

This application incorporates the entire contents of the foregoing application(s) herein by reference.

### TECHNICAL FIELD

Various embodiments relate generally to a serially connected ergonomic optical touch button.

### BACKGROUND

An electric switch is an electrical component for disconnecting or connecting a conducting path in an electrical circuit. For example, a switch may interrupt an electric current to divert the current path from one conductor to another. One example of an electric switch may be an electromechanical device including one or more sets of movable electrical contacts. For example, when a pair of the movable electrical contacts is touching, an electric current may pass between them, creating a current path. In some examples, connecting or disconnecting a current path may create a distinctive signal usable for signal communication.

Some control systems, such as a manufacturing system, may include electric switches to be operated manually, for example, a light switch or a push button to activate an actuator. For example, an activation signal may be connected to the actuator when the electrical switch is closed. In some examples, the electric switch may be configured to sense the position of a machine part, liquid level, pressure, or temperature. For example, the electric switch may generate an electronic signal to be transmitted to a controller based on a reading at the sensing element. The controller may, for example, generate control signals to other devices in a system based on the electronic signal.

### SUMMARY

Apparatus and associated methods relate to an inline capacitive touch switch (ICTS) with an ergonomic design to register with a body portion. In an illustrative example, the ICTS may include a single inline circuit board (SICB) extending in a horizontal axis, serially and operably connecting an input port and an output port. The SICB, for example, may include a capacitive touch input electrode directly disposed on a gap of the SICB. The ICTS may, for example, further include a housing enclosing the SICB entirely. For example, the housing may include at least one saddle depression. For example, each of the at least one saddle depression may, for example, be registered with the corresponding capacitive touch-input electrode. Various embodiments may advantageously provide a visually apparent touch area for the user to operably engage with the at least one capacitive touch input electrode through the housing.

Various embodiments may achieve one or more advantages. For example, some embodiments may advantageously provide water resistant housing to the SICB. Some embodiments may, for example, advantageously identify multiple input gestures received from the capacitive touch-input electrode. For example, some embodiments may advantageously provide remote control to a connecting edge device. Some embodiments may, for example, advantageously include a transparent portion of the housing to allow light to pass through the housing.

The details of various embodiments are set forth in the accompanying drawings and the description below. Other features and advantages will be apparent from the description and drawings, and from the claims.

### BRIEF DESCRIPTION OF THE DRAWINGS

FIG. 1A, FIG. 1B, FIG. 1C, FIG. 1D, and FIG. 1E depict an exemplary inline capacitive touch switch (ICTS) employed in a first illustrative use-case scenario.

FIG. 2A is a block diagram depicting an exemplary ICTS.

FIG. 2B is a flowchart illustrating an exemplary pick and reset method using an exemplary ICTS.

FIG. 2C is a flowchart illustrating an exemplary ICTS configuration method.

FIG. 3 depicts an exemplary inline capacitive touch switch (ICTS) employed in a second illustrative use-case scenario.

FIG. 4A and FIG. 4B depict a top perspective view and a bottom perspective view of an exemplary double saddled ICTS.

FIG. 5A and FIG. 5B are a schematic diagrams showing assembly views of exemplary double saddled ICTS.

FIG. 6A and FIG. 6B depict exemplary wiring diagrams of exemplary sensing circuits configured to receive remote programming inputs from an exemplary ICTS.

FIG. 7A and FIG. 7B are block diagrams of an exemplary static teaching operation and an exemplary dynamic teaching operation.

FIG. 8 is a flowchart illustrating an exemplary static teaching method using an exemplary ICTS.

FIG. 9 is a flowchart illustrating an exemplary dynamic teaching method using an exemplary ICTS.

FIG. 10A, FIG. 10B, FIG. 10C, FIG. 10D, FIG. 10E, and FIG. 10F are schematic diagrams showing an exemplary switch mounting bracket.

FIG. 11A and FIG. 11B are block diagrams depicting exemplary ICTS including a wireless antenna and a display.

FIG. 11C, FIG. 11D, FIG. 11E, and FIG. 11F depict various embodiments of an exemplary ICTS.

Like reference symbols in the various drawings indicate like elements.

### DETAILED DESCRIPTION OF ILLUSTRATIVE EMBODIMENTS

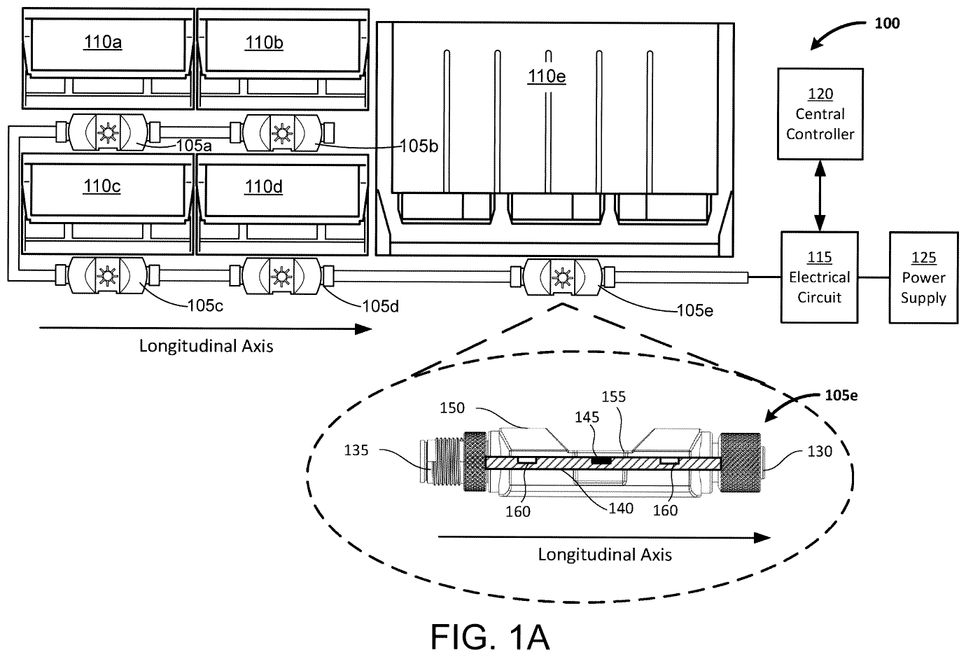

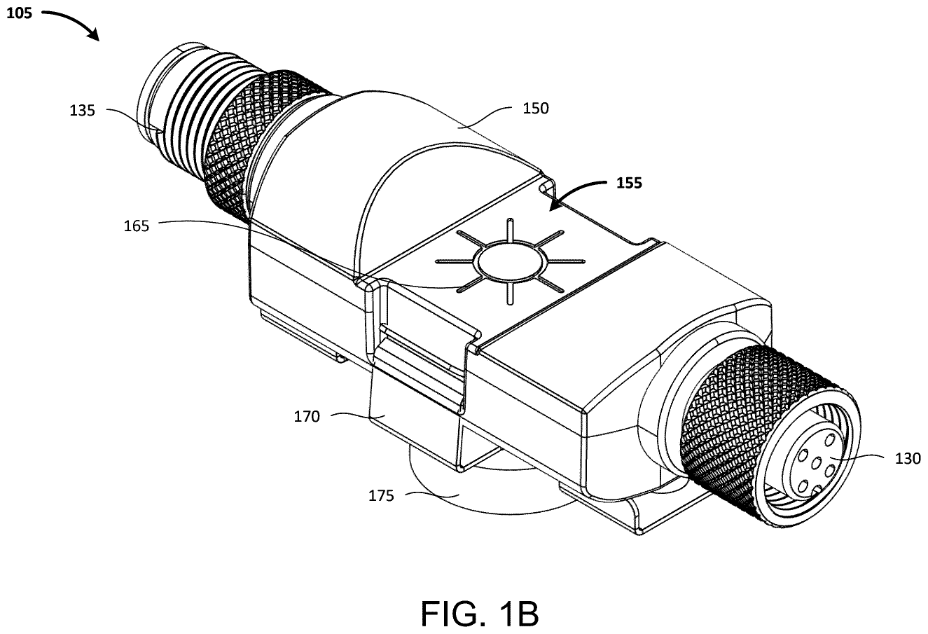

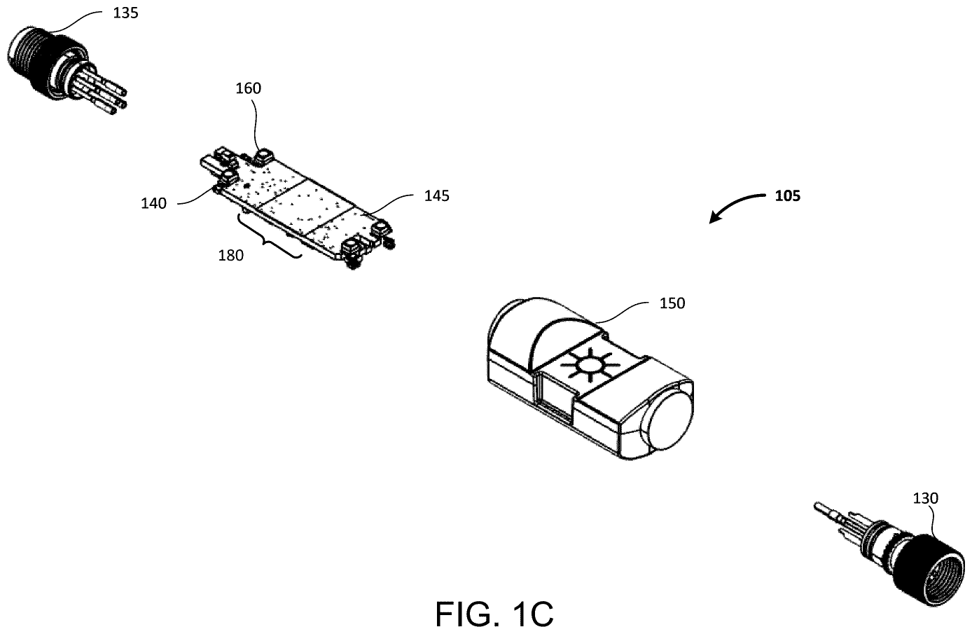

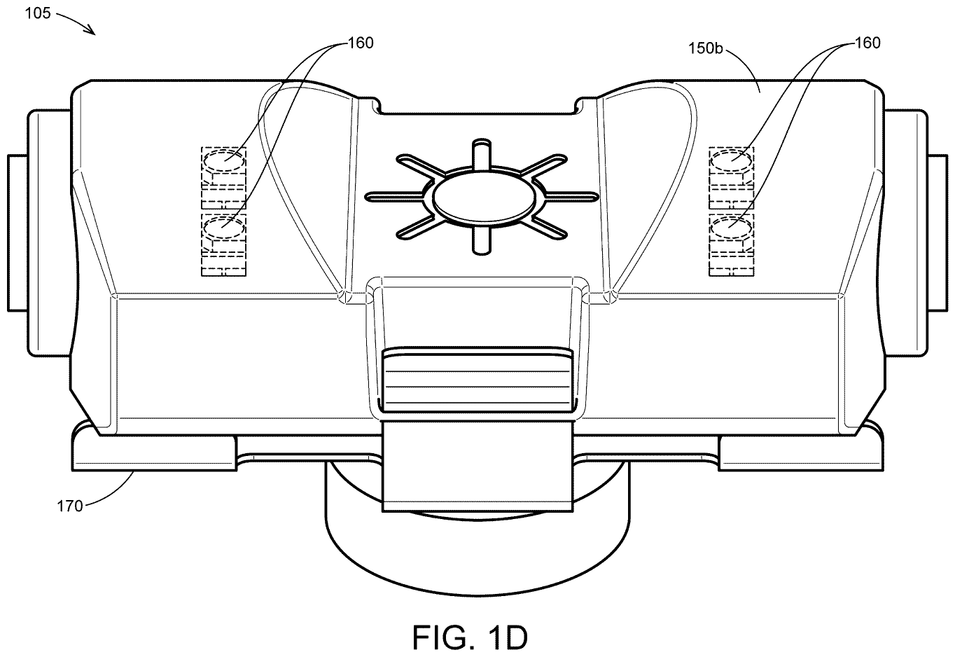

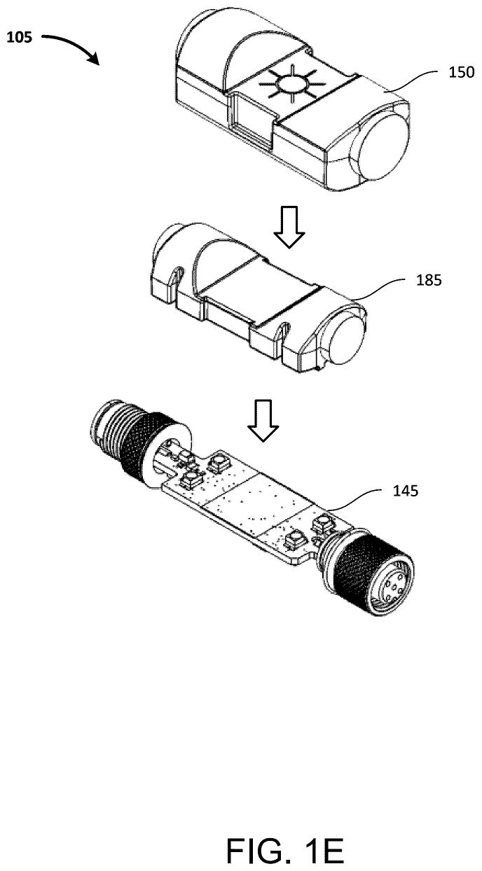

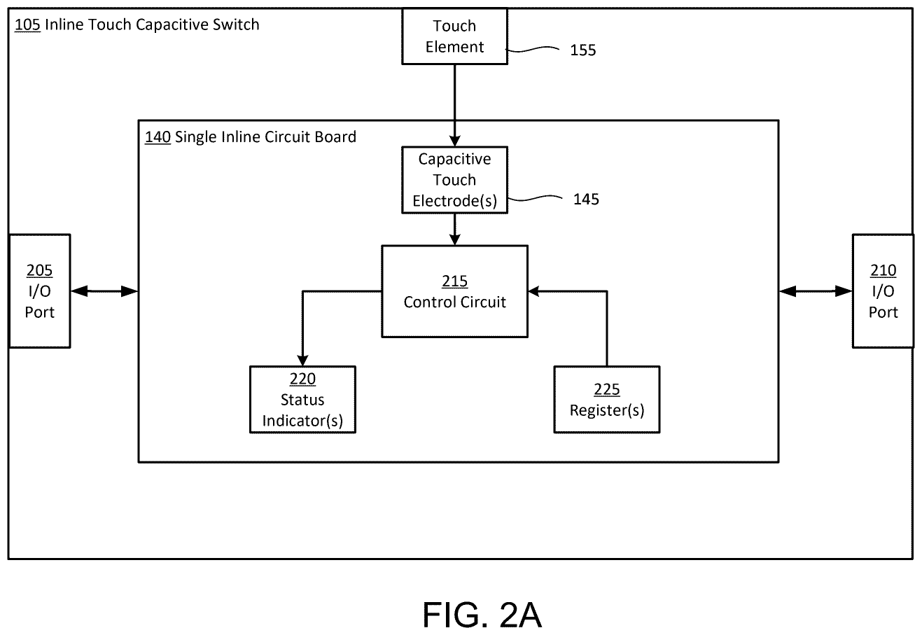

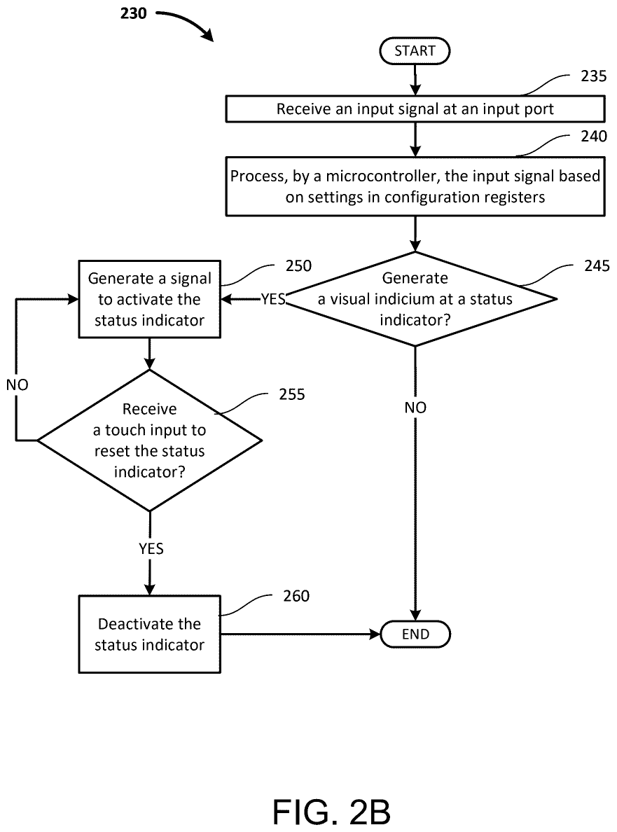

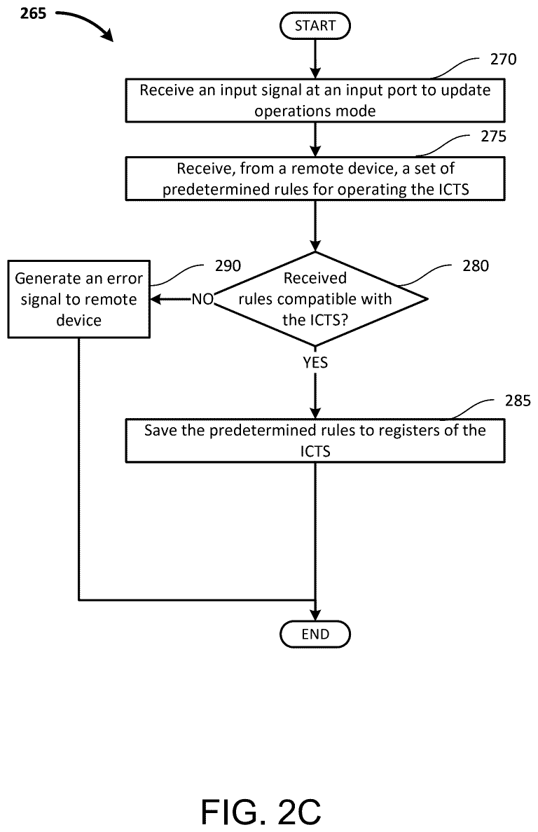

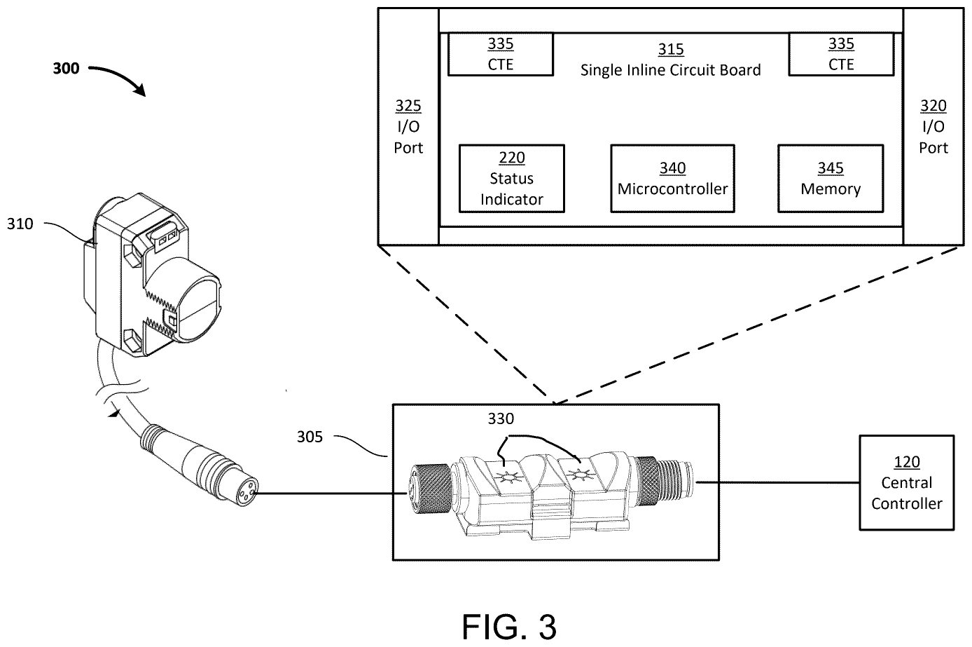

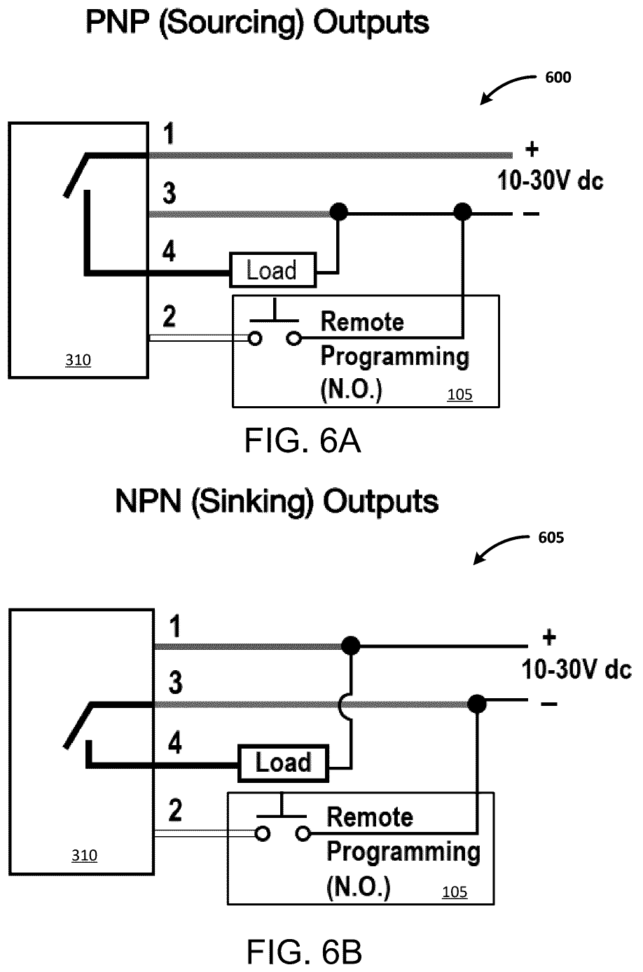

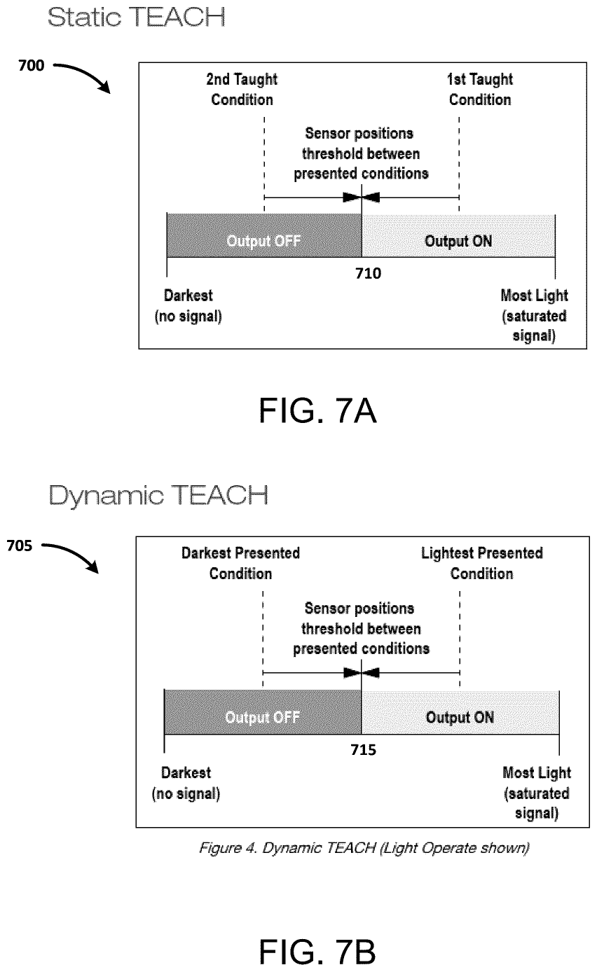

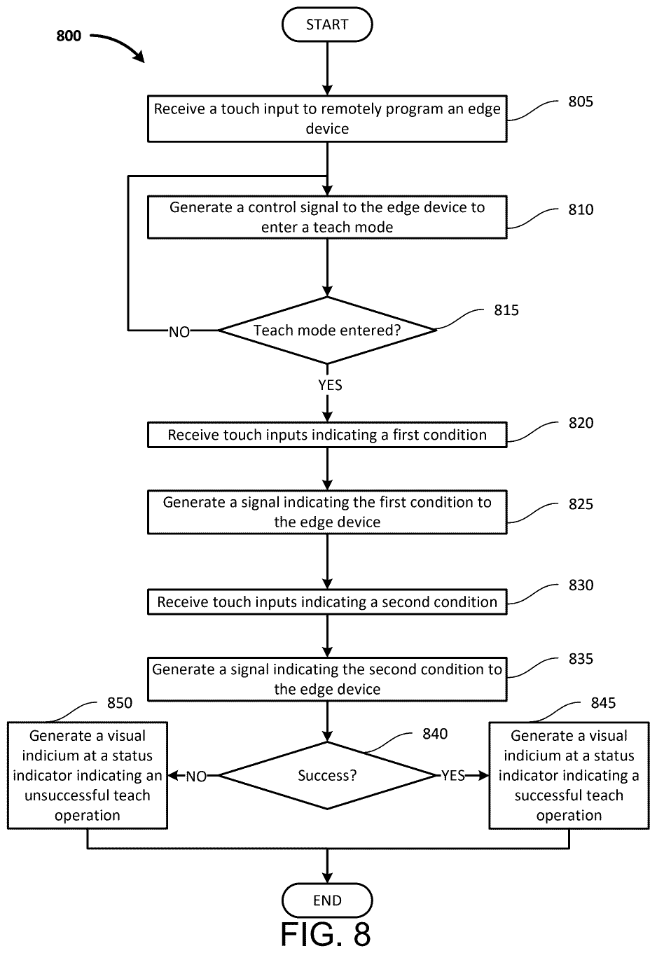

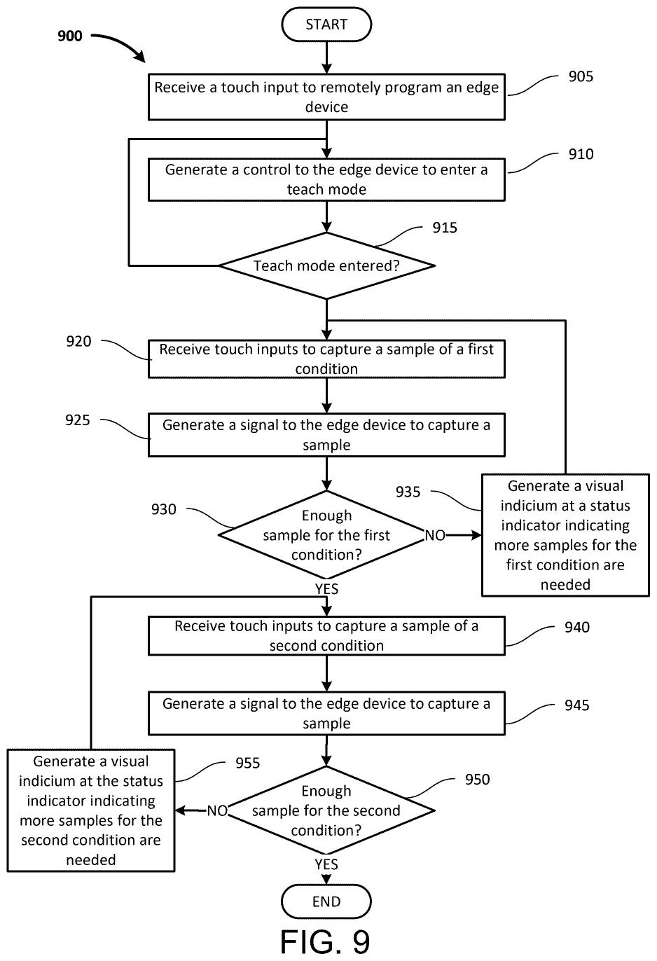

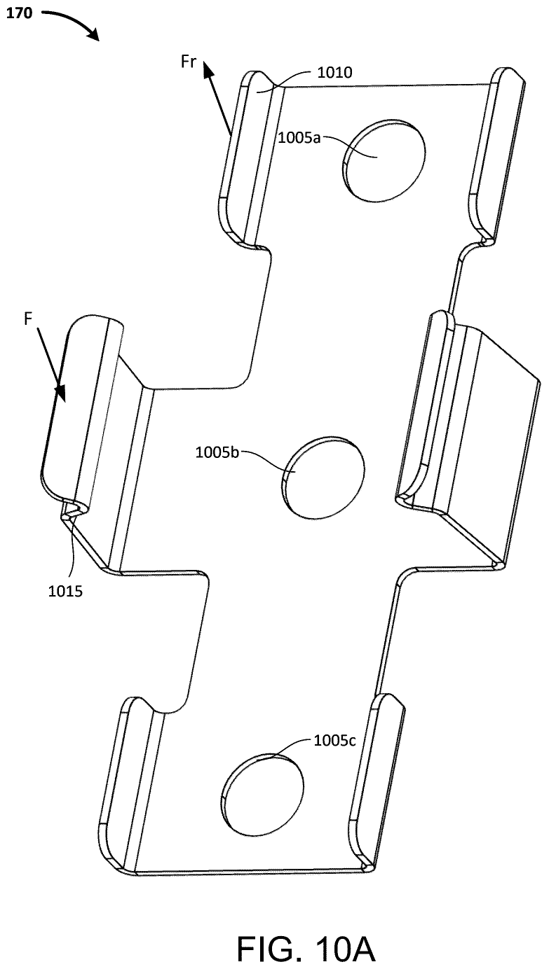

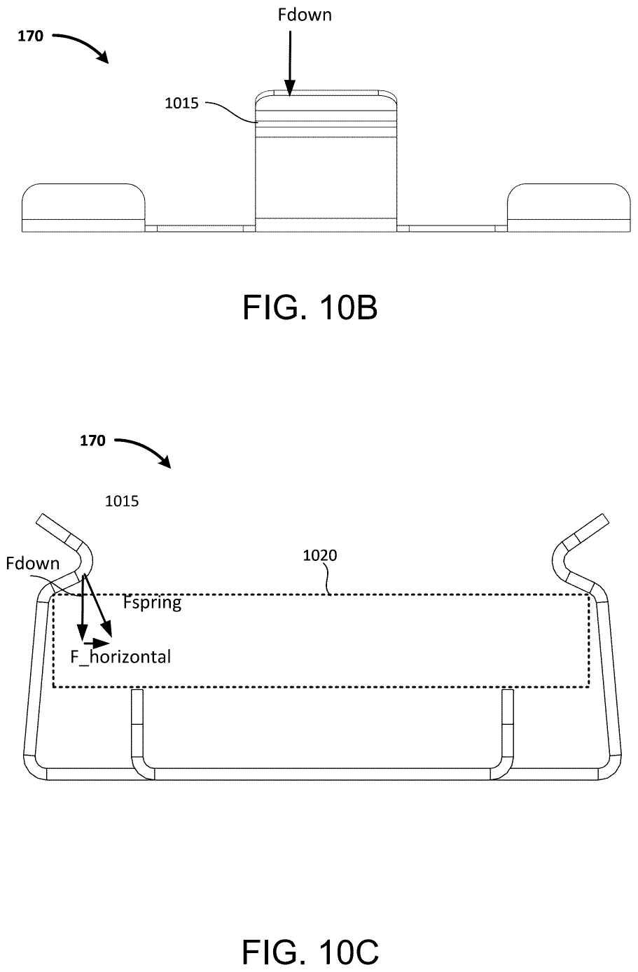

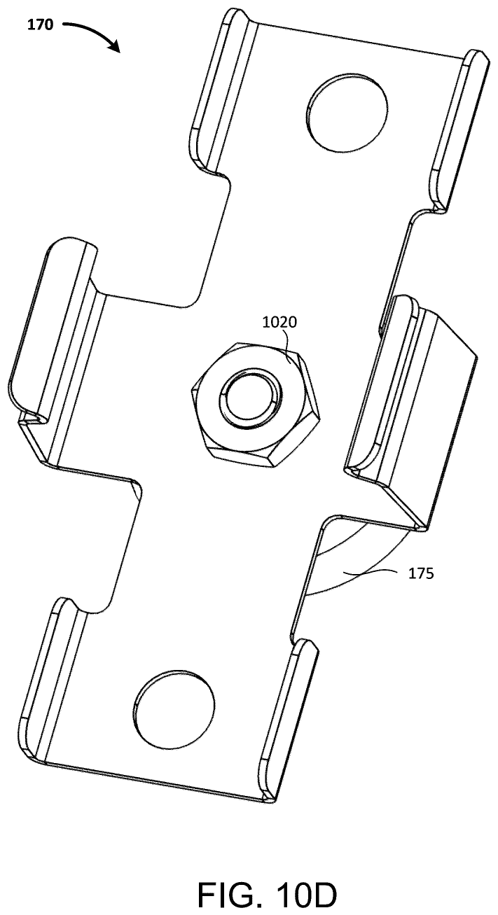

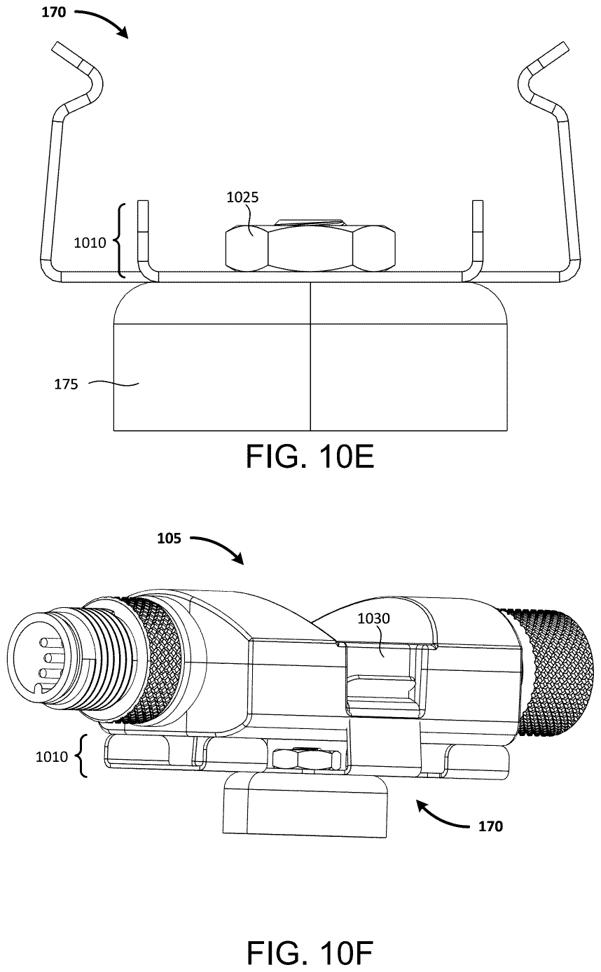

To aid understanding, this document is organized as follows. First, to help introduce discussion of various embodiments, an exemplary inline capacitive touch switch (ICTS) is introduced with reference to FIGS. 1A-2C. Second, that introduction leads to a description with reference to FIGS. 3-5B of some exemplary embodiments of the ICTS. Third, with reference to FIGS. 6A-7B, an exemplary remote teach operation is described in application to an exemplary ICTS. Fourth, with reference to FIG. 8-9, this document describes exemplary apparatus and methods useful for remote teach operations. Fifth, and with reference to FIGS. 10A-10F, the discussion turns to exemplary embodiments that illustrate mounting brackets for the ICTS. Finally, the document discusses further embodiments, exemplary applications and aspects relating to ICTS.

FIG. 1A, FIG. 1B, FIG. 1C, FIG. 1D, and FIG. 1E depict an exemplary inline capacitive touch switch (ICTS) employed in a first illustrative use-case scenario. In an exemplary manufacturing system 100 as shown in FIG. 1A, ICTS 105a, 105b, 105c, 105d, 105e are deployed. In this example, each of the ICTS 105a-e is extending along a longitudinal axis below a corresponding basket 110a, 110b, 110c, 110d, 110e. For example, the basket 110a-e may contain materials (e.g., components, parts) to be picked up during a manufacturing process.

The ICTS 105a-e are connected in-line with each other and to an electrical circuit 115. A central controller 120 is connected to the ICTS 105a-e via the electrical circuit 115. For example, the electrical circuit 115 may include other devices of the manufacturing system 100. For example, the electrical circuit 115 may include status indicators (e.g., tower light), actuators (e.g., robotic arms), and/or sensor devices (e.g., distance sensors, thermal sensors, safety light curtain). For example, the central controller 120 may transmit and receive control signals to the ICTS 105a-e.

In this example, the ICTS 105a-e may also be serially connected to a power supply 125 to receive input power. For example, the input power may be a low electric power (e.g., less than 1 mA, less than 5 mA) for small electronic loads. For example, the low input power may advantageously allow a small form factor for the ICTS 105a-e. In various implementations, the ICTS 105a-e extending along a single longitudinal axis may advantageously be easy to locate in a cable run line along an edge of a conveyor, machine, wall, or conduit run.

As shown in a close up diagram in FIG. 1A, the ICTS 105e includes an input port 130 connecting to the electrical circuit 115. For example, the input port 130 may receive input power from the power supply 125 and control signals from the central controller 120, via the electrical circuit 115. The ICTS 105e includes an output port 135. For example, the input port 130 and the output port 135 may transmit and receive IO-Link signals. For example, the input port 130 and the output port 135 may transmit and receive Modbus signals. For example, the input port 130 and the output port 135 may transmit and receive analog signals. For example, the input port 130 and the output port 135 may transmit and receive pulse width modulation (PWM) signals. For example, the input port 130 and the output port 135 may transmit and receive pulse frequency modulation (PFM) signals. In some implementations, the ICTS 105e may be configured to pass through control signals designated to one of the ICTS 105a-d downstream using the output port 135. Various implementations of signals to be received, transmitted, processed, and configured by the ICTS 105e are described in PCT Application Number PCT/US22/78548, titled “DISTRIBUTED COMMUNICATION AND CONTROL SYSTEM USING CONCURRENT MULTI-CHANNEL MASTER UNIT,” filed by Robert T. Fayfield et al., including coinventors of this application by Charles Dolezalek and William Theunissen. This application incorporates the entire contents of the foregoing application herein by reference.

In this example, the ICTS 105e includes a single circuit board 140. For example, the single circuit board 140 may be connected inline between the input port 130 and the output port 135. As shown, the single circuit board 140 includes a capacitive touch electrode (CTE 145). For example, the CTE 145 may be configured to detect a touch input via a capacitive touch (e.g., a human touch).

The ICTS 105e includes a housing 150 enclosed a single circuit board extending along the longitudinal axis between the input port 130 and the output port 135. As shown, the housing 150 is disposed around the single circuit board 140. In some examples, directly coupling the CTE 145 to the single circuit board 140 may advantageously reduce assembly costs.

A touch element 155, in this example, is formed in the housing 150 to advantageously help a user to locate an area for touch input. In some implementations, the touch element 155 is configured to register with the CTE 145 such that, for example, when a user places a finger in the touch element 155, the finger may be brought into operation contact with the CTE 145 through the housing 150. For example, a size of the touch element 155 may fit up to a reasonably large thumb.

Although the ICTS 105e includes only one touch element 155 to register with a body part of a user in this example, in other embodiments, the housing 150 may include two or more ergonomically designed depressions. In some implementations, the single circuit board 140 may include, corresponding to each of the depressions of the housing, a corresponding capacitive touch electrode. Each of the depressions may, for example, be configured to register with the corresponding capacitive touch electrode such that combination inputs may be received. For example, a user may selectively contact the capacitive touch electrodes in a specific combination to transmit a specific instruction to the ICTS through the housing.

The single circuit board 140 also includes light emitting diodes (LEDs 160). For example, the housing 150 may be at least partially translucent and/or transparent to allow the LEDs 160 to provide visual indicia through the housing 150. For example, the LEDs 160 may provide a visual indicium when the ICTS 105e is receiving power from the power supply 125 and is activated.

In some implementations, the ICTS 105a-e may be configured as a pick and reset system. As an illustrative example without limitation, when components or materials are required to be picked up from the basket 110e, the central controller 120 may activate the LEDs 160 of the ICTS 105e. For example, a worker may, upon picking up the materials from the basket 110e, reset the LEDs 160 by touching the CTE 145 of the ICTS 105e. For example, the ICTS 105e may transmit a signal to the central controller 120 via the electrical circuit 115 in response to a touch input from the user. In some examples, the central controller 120 may trigger to activate another ICTS to indicate another basket to be picked from.

In various embodiments, a ICTS (e.g., ICTS 105a-e) may include an inline circuit board (e.g., the single circuit board 140) serially connecting the input port 130 and the output port 135. For example, at least one capacitive touch-input circuit (e.g., the CTE 145) may be directly disposed on the inline single circuit board 140. For example, a housing enclosing the inline circuit board may include one or more saddle depressions that each register with one of the at least one capacitive touch-input circuit. For example, when a user places a body portion in the depression, the user may operably engage with the touch-input circuit through the housing.

As shown in FIG. 1B, a perspective of an exemplary ICTS 105 is shown. The exemplary ICTS 105 includes the housing 150. For example, the housing 150 may be translucent black to allow a light from an indicator (e.g., the LEDs 160) to be transmitted through the housing 150. In some examples, the housing 150 may be molded in other colors. For example, the housing 150 may be molded in translucent blue. For example, the housing 150 may be molded in translucent green. For example, the housing 150 may be molded in translucent red. In various implementations, the housing 150 may be mostly in solid color with only a portion of it being translucent to allow light from the indicator to pass through.

In some implementations, the housing 150 may be overmolded over the entire ICTS to cover the entire device with molten plastic. For example, the housing 150 may include a continuous material from connection to connection. In some implementations, the housing 150 may be overmolded over an entire circuit board (e.g., the single circuit board 140). For example, the housing 150 may, for example, extend over the single circuit board 140, the input port 130, and the output port 135 such that the ICTS 105 is advantageously protected entirely by the housing 150. For example, the exemplary ICTS 105 may advantageously be waterproof (e.g., IP67 compliant, IP68 compliant).

As shown, the housing 150 includes a symbol 165 at the touch element 155. In some implementations, the symbol 165 may advantageously visually assist a user of a touch input area of the ICTS 105. Various embodiments may include different designs of the symbols. In some embodiments, the housing 150 may be produced without the symbol 165 to reduce cost compared to making a housing with a double overmolding technique.

In this example, the ICTS 105 is coupled to a mounting bracket 170. For example, the mounting bracket 170 may couple the ICTS 105 to a rack holding the baskets 110a-e as described in FIG. 1A. As shown, the mounting bracket 170 is coupled to a coupling element 175. For example, the coupling element 175 may couple the mounting bracket 170 to the rack. Various embodiments of the mounting bracket 170 and the coupling element 175 are described with reference to FIGS. 10A-F.

As shown in FIG. 1C, an assembly view of the ICTS 105 is shown. The ICTS 105 includes the single circuit board 140 connected inline between the input port 130 and the output port 135. The single circuit board 140 includes four LEDs 160. For example, the housing 150 may be at least partially translucent and/or transparent to allow the LEDs 160 to provide visual indicia through the housing 150.

The single circuit board 140 includes a gap 180. For example, no integrated circuit component may be disposed at the gap 180. For example, the gap 180 may form an open touch point directly on the circuit board. In this example, the CTE 145 may be built into the single circuit board 140 in the gap 180. In some implementations, the CTE 145 may be a semiconductor (e.g., an Indium tin oxide (ITO)) film. For example, an entire ITO film disposed on the single circuit board 140 may be configured as the CTE 145. For example, the CTE 145 made with ITO film may advantageously be transparent to allow light to pass through. In some implementations, the CTE 145 may be electrically coupled to the single circuit board 140 via a Zero Insertion Force (ZIF) connector.

FIG. 1D shows an exemplary ICTS 105 having a black translucent housing 150b. The black translucent housing 150b is mounted on a mounting bracket 170. For example, the black translucent housing 150b may allow light emitted from enclosed LEDs 160 to pass through. In some implementations, the LEDs 160 may be a status indicator to provide visual feedback to show sequence progress or show current operation mode. For example, the LEDs 160 may show a sequence to indicate one or more components to be picked up from a corresponding basket 110a-e. In some implementations, the status indicator may include more than four LEDs. In some implementations, the status indicator may include four or less LEDs (e.g., 4, 3, 2, 1). For example, the status indicator may be configured to display count (e.g., to indicate how many units of components to be picked up). For example, the status indicator may be configured to flash to attract attention from a user.

In some implementations, the LEDs 160 may include RGB LEDs. For example, the LEDs 160 may be configured to change color based on control signals. In some implementations, the LEDs 160 may display a spectrally distributed indicium. For example, the LEDs 160 may be configured to display a different color corresponding to a different duty cycle. In some implementations, the LEDs 160 may display a temporally distributed indicium. For example, the LEDs 160 may be configured to display a sequence of patterns indicating a status of a manufacturing process. In some implementations, the LEDs 160 may display an intensity distributed indicium. For example, the LEDs 160 may be configured to display a varying intensity indicating a status of a corresponding basket.

FIG. 1E shows an exemplary ICTS 105 having an inner mold 185 under the housing 150 (e.g., an outer mold). For example, the inner mold 185 may be entirely encapsulated by the outer mold. In some implementations, the housing 150 may include more than one layer. In some implementations, multiple layers of housing may advantageously reduce shrinkage and imperfection caused by a one-time molding process. In some examples, a multi-layered housing may advantageously allow layers of different colors and various levels of translucence across layers.

FIG. 2A is a block diagram depicting an exemplary ICTS 105. As shown, the ICTS 105 includes the single circuit board 140. In this example the single circuit board 140 is coupled in-line with an I/O port 205 and an I/O port 210. For example, the I/O port 205 and the I/O port 210 may be configured to transmit and receive signals. For example, the I/O port 205 and/or the I/O port 210 may receive control signals (e.g., an activation signal of the LEDs 160) from the central controller 120. For example, the I/O port 205 and/or the I/O port 210 may transmit control signals (e.g., a reset signal upon receiving a touch input) from the central controller 120. For example, the I/O port 205 and/or the I/O port 210 may pass through control signals from the central controller 120 to a serially coupled ICTS downstream.

The single circuit board 140 includes a control circuit 215. The control circuit 215 receives input from the touch element 155 via the CTE 145. In some implementations, the control circuit 215 may transmit a signal to the central controller 120 when a touch input is received from the touch element 155.

As shown, the single circuit board 140 further includes a status indicator 220 and one or more register(s) 225. For example, the status indicator 220 may include LEDs 160. For example, the status indicator 220 may be configured to provide visual feedback (e.g., of a touch at the touch element 155) to a user.

In some implementations, the control circuit 215 may be configured to process control signals received at and I/O port 205 and/or the I/O port 210 based on settings stored in the register(s) 225. For example, the control circuit 215 may display a specific sequence of patterns based on a predetermined setting stored in the register(s) 225.

In some implementations, the control circuit 215 may be configured to receive and identify between multiple touch gestures. For example, the control circuit 215 may also process combination or process of touch input. For example, a user may use various touch sequences (e.g., temporally distributed touch sequences) to switch on different conductors. For example, the different touch sequence may be used to control multiple edge devices (e.g., different tower lights). In various implementations, the control circuit 215 and the register(s) 225 may be configured to operate in three or more operation modes.

In some embodiments, the CTE 145 may include an array (e.g., arranged in 1-dimensional, 2-Dimensional, 3-Dimensional pattern(s)) of electrodes. For example, the control circuit 215 may be configured to detect one or more gestures activated on the array of CTE 145. For example, the gestures may include a sliding gesture. For example, the gestures may include a rotation gesture. In some implementations, the control circuit 215 may generate an output signal at the I/O port 205 and/or the I/O port 210 based on the identified gestures. For example, the control circuit 215 may operate in different operating mode based on the identified gesture. For example, the control circuit 215 may store a value as a function of the identified gesture to the register(s) 225.

FIG. 2B is a flowchart illustrating an exemplary pick and reset method using an exemplary ICTS. For example, the method may be performed by the ICTS 105 as described with reference to FIG. 2A. For example, the method 230 may be performed by the control circuit 215 based on a predetermined setting stored in the register(s) 225. For example, the method 230 may be performed by the ICTS 105a-e described in FIG. 1A to indicate materials to be picked up from the baskets 110a-e. In this example, the method 230 begins when an input signal is received at an input port in step 235. For example, the central controller 120 may transmit a control signal to the ICTS 105e. Next, the input signal is processed by a microcontroller based on settings in configuration registers in step 240.

In a decision point 245, it is determined whether a visual indicium is to be generated at a status indicator. For example, the control circuit 215 may determine whether the status indicator 220 is to be activated based on the received control signal and the settings in the register(s) 225. If it is determined that a visual indicium is not to be generated at a status indicator, the method 230 ends. For example, the received control signal may be determined to be passed through to another ICTS or another device downstream.

If it is determined that a visual indicium is to be generated at a status indicator, in step 250, a signal is generated to activate the status indicator. Next, in a decision point 255, it is determined whether a touch input is received to reset the status indicator. For example, the control circuit 215 may process a received touch input based on predetermined settings in the register(s) 225. For example, the predetermined settings may indicate only a specific sequence and/or combination of touch input indicate a reset to the status indicator 220. If the status indicator is not to be reset, the step 250 is repeated. If the status indicator is to be reset, the statue indicator is deactivated in step 260 and the method 230 ends.

FIG. 2C is a flowchart illustrating an exemplary ICTS configuration method 265. For example, the method 265 may be performed by the control circuit 215. In this example, the method 265 begins in step 270 when an input signal is received at an input port to update an operation mode. For example, the input signal may be transmitted from the central controller 120.

In step 275, a set of predetermined rules for operating the ICTS is received from a remote device. For example, the ICTS 105 may receive a set of predetermined rules (e.g., a firmware update) from a remote computer via the electrical circuit 115 and/or the central controller 120.

In a decision point 280, it is determined whether the received rules are compatible with the ICTS. For example, the control circuit 215 may check whether a format of the received signal is compatible with an acceptable protocol. If the received rules are compatible with the ICTS, the predetermined rules are saved to registers of the ICTS in step 285, and the method 265 ends. For example, the received predetermined rules may be saved to the register(s) 225. If the received rules are not compatible with the ICTS, an error signal is generated to the remote device in step 290, and the method 265 ends.

FIG. 3 depicts an exemplary inline capacitive touch switch (ICTS) employed in a second illustrative use-case scenario. In the scenario 300, an ICTS 305 is operably coupled to an edge device 310 and the central controller 120. For example, the edge device 310 may be an optical distance sensor. In some implementations, the ICTS 305 may be an inline touch input to remotely control the edge device 310.

As an illustrative example, the ICTS 305 may control the edge device 310 to, for example, return a sensor reading to be transmitted to the central controller 120. For example, the central controller 120 may be determined to make a reading at the edge device 310. However, for example, some settings may need to be checked before a reading to be taken. For example, the central controller 120 may transmit a signal to the ICTS 305 to activate the status indicator 220 in the ICTS 305. A user, for example, upon seeing the activated status indicator 220, may check the setting and activate the reading remotely by operating the ICTS 305. After receiving the reading from the edge device 310, for example, the ICTS 305 may transmit the readings to the central controller 120.

In a block diagram shown in FIG. 3, the ICTS 305 includes a single inline circuit board 315. The single inline circuit board 315 connects an I/O port 320 and an I/O port 325. The ICTS 305 includes, in this example, two touch saddles 330. The single inline circuit board 315 includes two CTE 335. For example, each of the CTE 335 may correspond to one of the two touch saddles 330 In this example, the single inline circuit board 315 also includes a microcontroller 340, a memory 345, and the status indicator 220. In some implementations, the microcontroller 340 may be configured to perform operations of instructions stored in the memory 345. In some implementations, the microcontroller 340 may be configured to identify touch events received from the CTE 335. For example, the touch events may be identified by a time of touching at the two touch saddles 330. For example, the microcontroller 340 may identify that a touch of less than two seconds is to activate detection at the edge device 310. For example, the microcontroller 340 may identify that a touch of more than two seconds is to activate a teaching mode at the edge device 310.

In some implementations, the ICTS 305 may include multiple depressions for registering a body portion of a user. For example, a multi-touch ICTS may include three touch saddles to control a tower light. For example, the multi-touch ICTS may include three touch inputs. For example, each of the three touch inputs may be connected to a different input pin of a tower light controller.

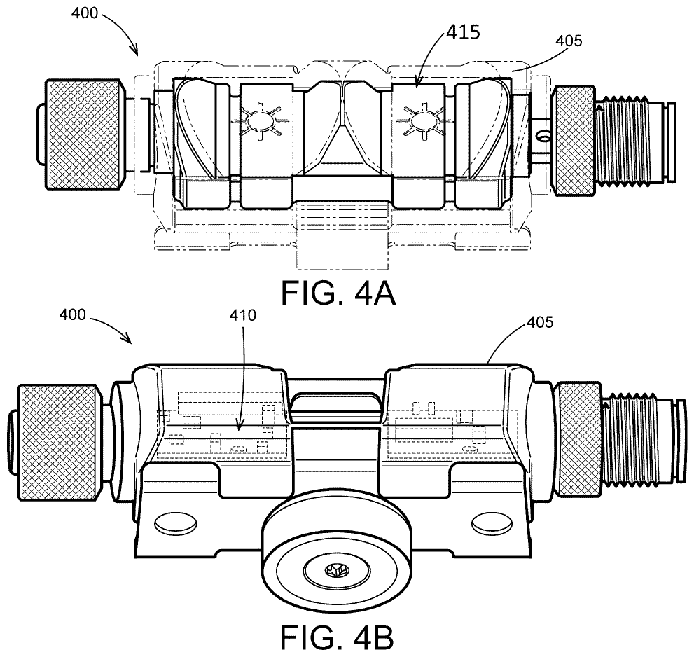

FIG. 4A and FIG. 4B depict a top perspective view and a bottom perspective view of an exemplary double saddled ICTS 400. As shown in FIG. 4A, the double saddled ICTS 400 includes a housing 405 enclosing an inner module 415. As shown in FIG. 4B, the double saddled ICTS 400 includes the housing 405 enclosing an inline circuit board 410 (e.g., the single inline circuit board 315). For example, the housing 405 may be overmolded over a circuit including the inline circuit board 410 entirely. For example, the inline circuit board 410 may be enclosed within the inner module 415. In some implementations, the housing 405 is not overmolded so that the manufacturing cost of the exemplary double saddled ICTS 400 may be advantageously reduced.

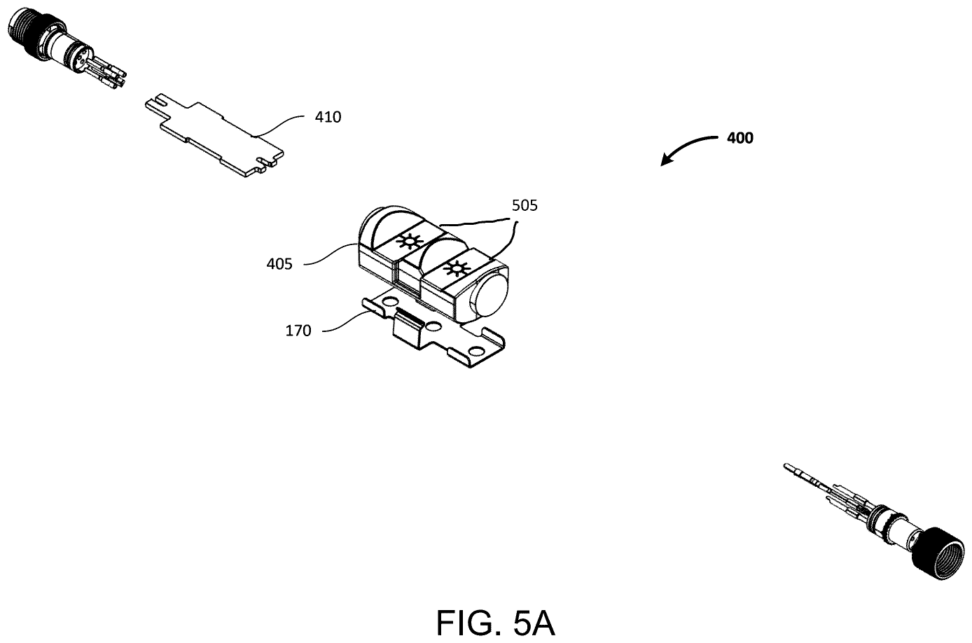

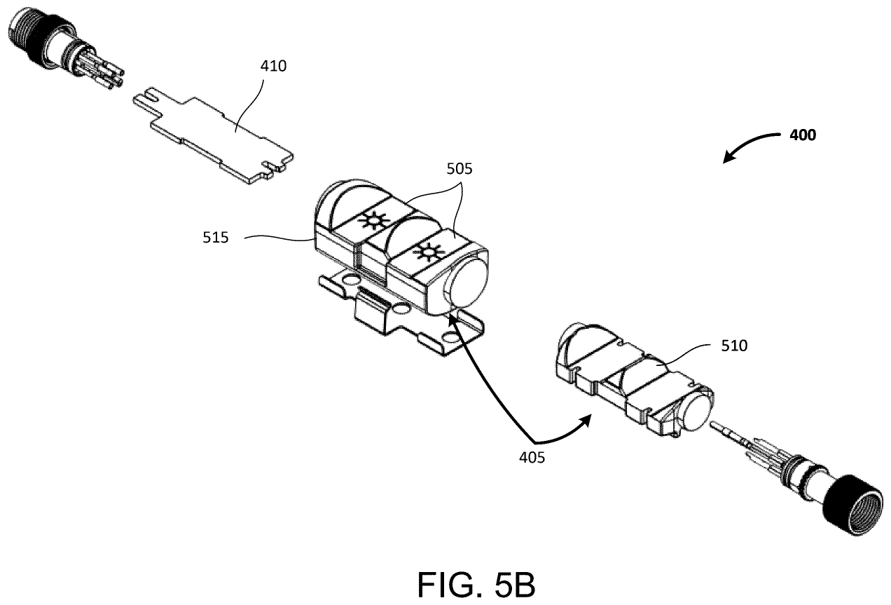

FIG. 5A and FIG. are a schematic diagrams showing assembly views of exemplary double saddled ICTS.

As shown in FIG. 5A, the ICTS 400 includes the inline circuit board 410 enclosed in the housing 405. The housing 405 includes two saddles 505. For example, each of the saddles 505 may advantageously facilitate touching of a body portion. The double saddled ICTS 400 is, in this example, mounted using the mounting bracket 170.

As shown in FIG. 5B, the housing 405 includes an inner layer 510 and an outer layer 515. For example, the inner layer 510 and the outer layer 515 may have different color to advantageously provide multi-color housing and various level of translucence for the double saddled ICTS 400.

FIG. 6A and FIG. 6B depict exemplary wiring diagrams of exemplary sensing circuits configured to receive remote programming inputs from an exemplary ICTS. FIG. 6A shows an exemplary circuit 600 having sourcing (PNP) outputs. FIG. 6B shows an exemplary circuit 605 having sinking (NPN) outputs. In both examples, the ICTS 105 is connected to the edge device 310. For example, a user may advantageously remotely program the edge device 310 by operating the ICTS 105.

FIG. 7A and FIG. 7B are block diagrams of an exemplary static teach operation 700 and an exemplary dynamic teach operation 705. For example, the operations 700, 705 may be used to train an edge device (e.g., the edge device 310). For example, the operations 700, 705 may be used to train an optical distance sensing device. In some implementations, the microcontroller 340 may advantageously be used to generate a control signal to remotely control the teaching operations 700, 705. In some implementations, the edge device and an ICTS may be connected as shown in FIGS. 6A-B to enable remote programming.

As shown in FIG. 7A, the static teach operation 700 may be used to locate a single switching threshold (e.g., a switch point 710). For example, the switch point 710 may be an optimal location between the two taught conditions. For example, two taught conditions may include a condition when an authorized object is detected on a conveyor belt, and/or may include a condition when an authorized object is not detected on a conveyor belt. As shown, at the switch point 710, an Output ON condition is located on one side, and the Output OFF condition is located on another side.

In this example, during Static TEACH, a first condition taught is located in the ON condition, and a second condition taught is located in the OFF condition. For example, the switch point 710 may be determined by combining the first condition and the second condition.

In some implementations, the first condition may be determined by a reading at a time when a signal is received remotely from an ICTS (e.g., the ICTS 305). In some implementations, the second condition may be determined by a reading at a time when a signal is received remotely from an ICTS (e.g., the ICTS 305). For example, the microcontroller 340 may generate the control signal to capture the conditions when a touch input is held at the two touch saddles 330 for two seconds. In some implementations, after the edge device entered the teach mode, the ICTS 305 may set a condition at the edge device based on received inputs from the CTE 335. In some examples, the Output ON and OFF conditions may be reversed by switching the TEACH order or by changing the Light-/Dark-Operate setting in a setup mode of the edge device.

As shown in FIG. 7B, the dynamic teaching operation 705 includes a single switching threshold (e.g., a switch point 715). For example, the dynamic teaching operation 705 may be used to teach during actual sensing conditions. In some implementations, an edge device (e.g., an optical distance sensor) may take multiple samples of light and dark conditions and automatically set the threshold at an optimum level. In various embodiments, the ICTS 305 may be configured to transmit a control signal to the edge device to capture the samples of light and/or dark conditions.

FIG. 8 is a flowchart illustrating an exemplary static teaching method 800 using an exemplary ICTS. For example, the ICTS 305 may perform the exemplary static teaching method 800 to train an object detection sensor. In this example, the method 800 begins when a touch input is received to remotely program an edge device (e.g., an object detection sensor) in step 805. For example, the ICTS 305 may receive a sequence or pattern of touch inputs from the two touch saddles 330 to remotely start the teaching mode. Next, in step 810, a control signal is generated to the edge device to enter a teach mode. For example, the microcontroller 340 may generate a control signal based on predetermined rules stored in the memory 345. For example, the control signal may be transmitted via the I/O ports 320, 325.

In a decision point 815, it is determined whether a teach mode is entered. For example, the microcontroller 340 may wait for a confirmation signal from the edge device from the I/O ports 320, 325. If the teach mode is not entered, the step 810 is repeated. For example, the microcontroller 340 may time out the wait for the confirmation signal. If the teach mode is entered, in step 820, touch inputs indicating a first condition are received. For example, the microcontroller 340 may determine an input sequence from the two touch saddles 330 to indicate a numerical value for the first condition. In step 825, a signal indicating the first condition is generated to the edge device. For example, the microcontroller 340 may generate the signal based on predetermined rules in the memory 345. For example, the predetermined rules may include the type of the edge device to generate the signals in a compatible protocol.

In step 830, touch inputs indicating a second condition are received. For example, the microcontroller 340 may determine an input sequence from the two touch saddles 330 to indicate a numerical value for the first condition. In step 835, a signal indicating the first condition is generated to the edge device. For example, the microcontroller 340 may generate the signal based on predetermined rules in the memory 345.

In a decision point 840, it is determined whether the teach operation is a success. For example, the ICTS 305 may receive a status signal from the edge device indicating the success of the operation. If the teach operation is a success, a visual indicium is generated at a status indicator indicating a successful teach operation in step 845, and the method 800 ends. For example, the microcontroller 340 may generate a solid green light at the status indicator 220. If the teach operation is not a success, a visual indicium is generated at a status indicator indicating an unsuccessful teach operation in step 850, and the method 800 ends. For example, the microcontroller 340 may generate a flashing red light at the status indicator 220.

FIG. 9 is a flowchart illustrating an exemplary dynamic teaching method 900 using an exemplary ICTS. In some implementations, the method 900 may be performed by the same devices that perform the method 800 as described in FIG. 8. For example, the edge device may include a static teach mode and a dynamic teach mode. In some implementations, the method 900 may be performed in an edge device that may only allow dynamic teach operation.

In this example, the method 900 begins when a touch input is received to remotely program an edge device (e.g., an object detection sensor) in step 905. For example, the ICTS 305 may receive a sequence or pattern of touch inputs from the two touch saddles 330 to remotely start the teaching mode. Next, in step 910, a control signal is generated to the edge device to enter a teach mode. For example, the microcontroller 340 may generate a control signal based on predetermined rules stored in the memory 345. For example, the control signal may be transmitted via the I/O ports 320, 325.

In a decision point 915, it is determined whether a teach mode is entered. For example, the microcontroller 340 may wait for a confirmation signal from the edge device from the I/O ports 320, 325. If the teach mode is not entered, the step 910 is repeated. If the teach mode is entered, in step 920, touch inputs are received to capture a sample of a first condition. For example, a touch gesture of “sample capture” may be received by the ICTS 305. For example, the microcontroller 340 may determine the sample capture gesture based on predetermined rules in the memory 345. In step 925, a signal is generated to the edge device to capture a sample. For example, the microcontroller 340 may generate the signal based on predetermined rules in the memory 345 to capture a sample of the first condition.

In a decision point 930, it is determined whether enough samples are captured for the first condition. For example, the microcontroller 340 may read a register in the edge device to determine whether enough samples are captured. If not enough samples are captured for the first condition, in step 935, a visual indicium is generated at a status indicator indicating more samples for the first condition are needed, and the step 920 is repeated. For example, the microcontroller 340 may generate a yellow light at the status indicator 220 to indicate more samples are needed.

If enough samples are captured, in step 940, touch inputs are received to capture a sample of a second condition. For example, a touch gesture of “sample capture” may be received by the ICTS 305. For example, the microcontroller 340 may determine the sample capture gesture based on predetermined rules in the memory 345. In step 945, a signal is generated to the edge device to capture a sample. For example, the microcontroller 340 may generate the signal based on predetermined rules in the memory 345 to capture a sample of the second condition.

In a decision point 950, it is determined whether enough samples are captured for the second condition. For example, the microcontroller 340 may read a register in the edge device to determine whether enough samples are captured. If not enough samples are captured for the second condition, in step 955, a visual indicium is generated at a status indicator indicating more samples for the second condition are needed, and the step 940 is repeated. For example, the microcontroller 340 may generate a yellow light at the status indicator 220 to indicate more samples are needed. If enough samples are captured for the second condition, the method 900 ends.

FIG. 10A, FIG. 10B, FIG. 10C, FIG. 10D, FIG. 10E, and FIG. 10F are schematic diagrams showing an exemplary mounting bracket (e.g., the mounting bracket 170). For example, an ICTS may use the mounting bracket 170 to be coupled to a rack or a fixture. In some implementations, the mounting bracket 170 may advantageously provide flexibility for the ICTS to be mounted on different surfaces including, for example, screw base, magnet, Deutsches Institut ür Normung (DIN) rail. As shown in FIG. 10A, the mounting bracket 170 includes coupling apertures 1005a, 1005b, 1005c. For example, the apertures 1005a-c may allow the screw head to be attached. For example, the apertures 1005 a-c may fit an 8020 aluminum extrusion. In some implementations, the mounting bracket 170 may include (e.g., instead of having the coupling apertures 1005a-c and/or additional to the coupling apertures 1005a-c) adhesive (e.g., a double sided adhesive tape, a VHB™ tapes). VHB is a registered trademark of 3M Company headquartered in Maplewood, Minnesota. For example, the adhesive may be applied to the bracket 170. For example, the bracket 170 may be coupled with a surface having the adhesive to another surface as another form of mounting.

The mounting bracket 170, in this example, includes a step 1010. For example, the step 1010 may be a hard step. For example, the step 1010 may be a spring step. As shown in FIG. 10A, the step 1010 may exert a force Fr onto an ICTS mounted on the mounting bracket 170. In some implementations, the step 1010 may elevate an ICTS mounted on the mounting bracket 170 to provide space for a screw head.

The mounting bracket 170 also includes a ramp 1015. In some implementations, the ramp 1015 may exert a downward force (F) at a receiving groove at the housing 150 of an ICTS. For example, the ramp 1015 may advantageously maintain the downward force to reduce vibration of the ICTS.

FIG. 10B shows a side view of the exemplary mounting bracket 170. FIG. 10C shows a front view of the exemplary mounting bracket 170. As shown in FIG. 10C, the ramp 1015 may exert a spring like force (Fspring) towards a mounted ICTS 1020. A downward force (Fdown) and an horizontal force (F_horizontal) are generated by the Fspring. Accordingly, vibration at the mounted ICTS 1020 may be reduced by the Fdown.

As shown in FIG. 10D, the coupling element 175 is coupled to the mounting bracket 170 by a screw head 1025. As shown in FIG. 10E, in a front view of the mounting bracket 170, the step 1010 is higher than the screw head 1025 to elevate an ICTS above the screw head 1025. This is also shown in FIG. 10F. As shown in FIG. 10F, the ICTS 105 is mounted on the mounting bracket 170. As shown, the ICTS 105 include a groove 1030 to be releasably coupled to the ramp 1015.

In various embodiments, the ICTS may include input/output ports of a quick disconnect (QD) connection. In some examples, the ICTS may include a cable connection. In some examples, the ICTS may include a pigtail connection.

In some embodiments, the CTE 145 may be at the same height as the rest of the housing 150.

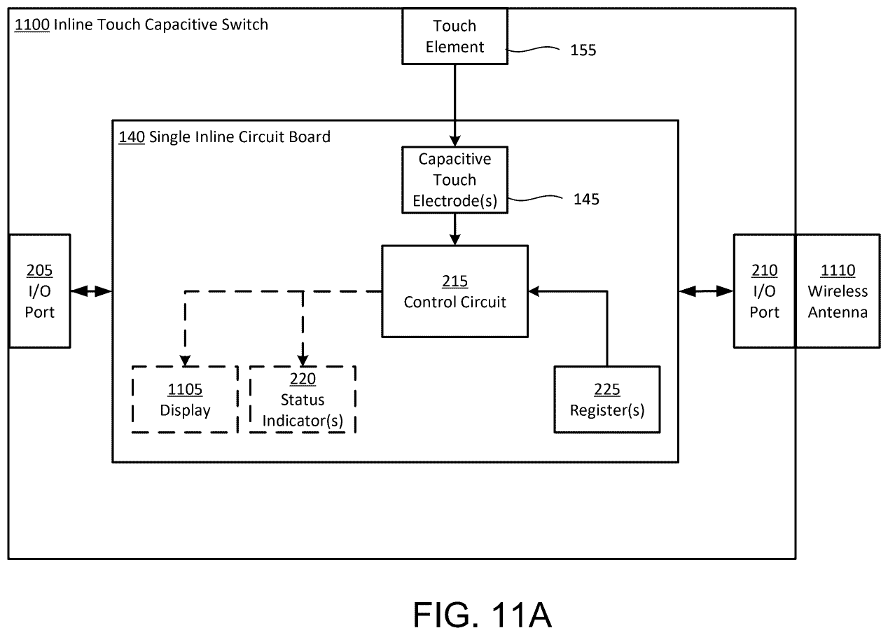

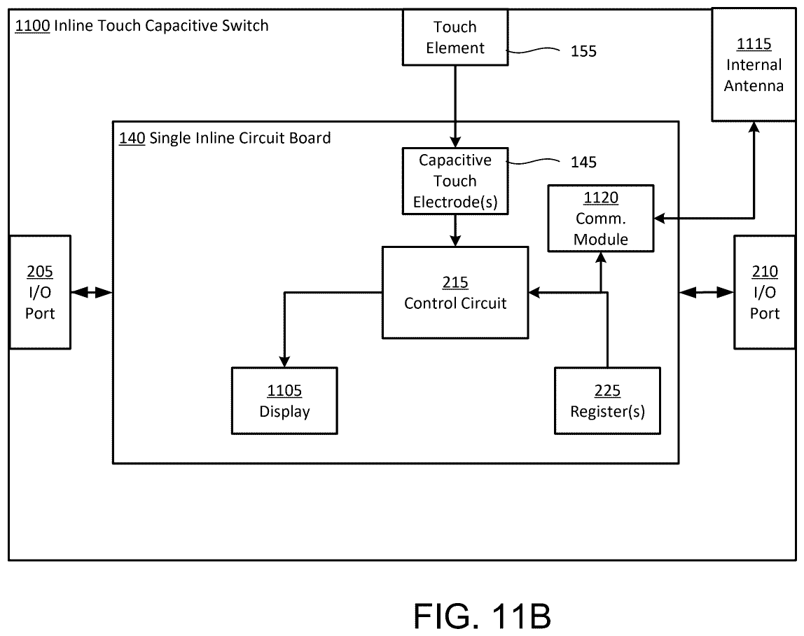

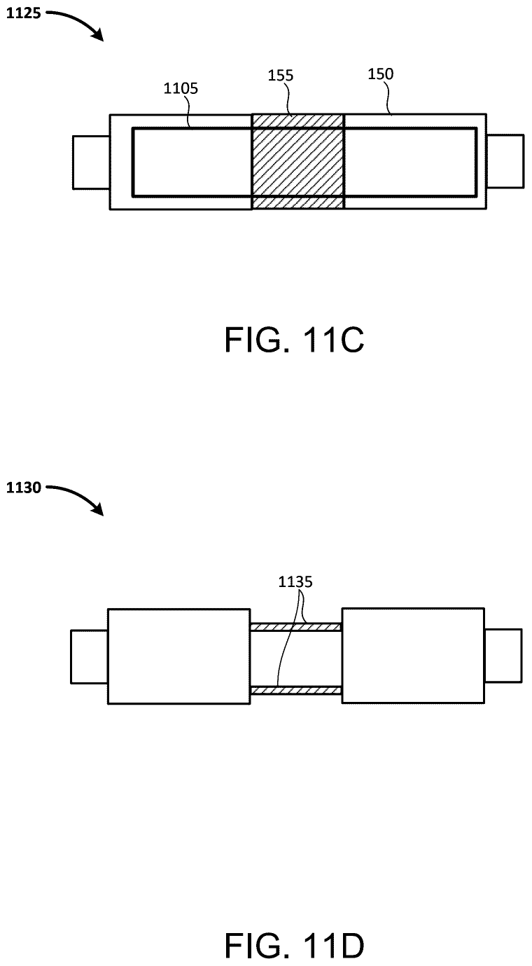

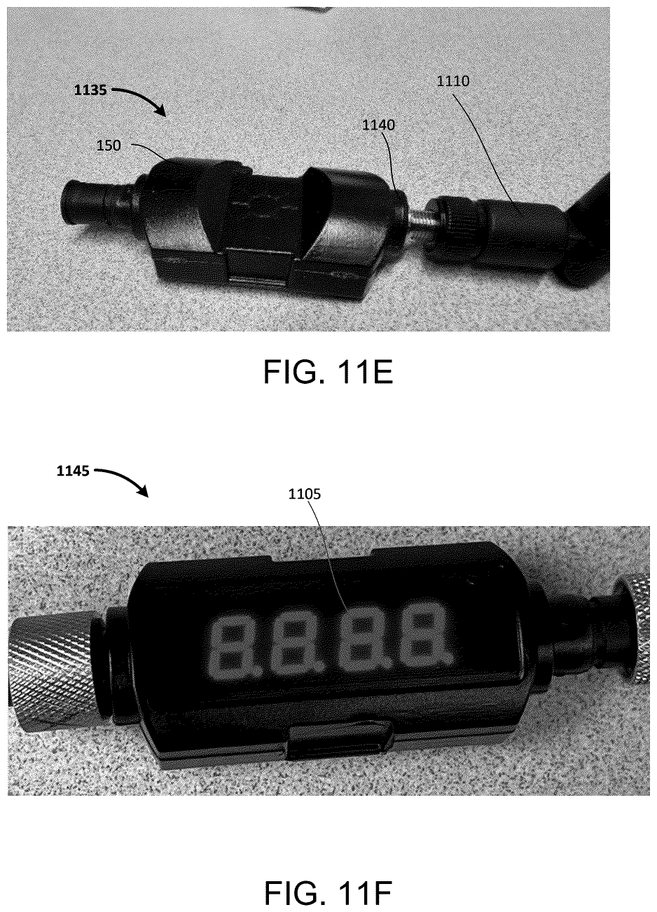

FIG. 11A and FIG. 11B are block diagrams depicting exemplary ICTS including a wireless antenna and a display. In this example, an ICTS 1100 may optionally include a display 1105 and/or the status indicator 220. For example, the ICTS 1100 may include the display 1105 without the status indicator 220. For example, the ICTS 1100 may include the status indicator 220 without the display 1105. For example, the ICTS 1100 may include both the display 1105 and the status indicator 220. The display 1105, for example, may include LED displays. For example, the display 1105 may include liquid crystal (LCD) displays. For example, the display 1105 may be a multiple digit display (e.g., 7 segment, 14 segment).

As shown, the ICTS 1100 also includes a wireless antenna 1110 operably coupled to the I/O port 210. In some examples, the ICTS 1100 may include the wireless antenna 1110 coupled to the I/O port 205. In some examples, the ICTS 1100 may be coupled to both the I/O port 205 and the I/O port 210. In some implementations, the ICTS 1100 may receive and/or transmit wireless communication signals. In some implementations, the I/O port 210 may include a wireless connector (e.g., an SMA connector) configured to receive the wireless antenna 1110.

In some implementations, as shown in FIG. 11B, the ICTS 1100 includes an internal antenna 1115 connected to a communication module 1120. For example, the communication module 1120 may be configured to generate wireless signal at the internal antenna 1115 based on control signals received from the control circuit 215. For example, the communication module 1120 may generate input signals to the control circuit 215 based on signals received form the internal antenna 1115.

FIG. 11C, FIG. 11D, FIG. 11E, and FIG. 11F depict various embodiments of an exemplary ICTS. As shown in FIG. 11C, an ICTS 1125 may include the display 1105 enclosed within the housing 150. For example, the display 1105 may be disposed on top of the touch element 155. In some examples, the display 1105 may display a number. In some examples, the display 1105 may display a text. In some implementations, the display 1105 may display graphics. In some examples, the display 1105 may display a rolling text. As shown in FIG. 11C, an ICTS 1130 may include touch elements 1135 on an opposite sides of the ICTS 1130.

As shown in FIG. 11E, an exemplary ICTS 1135 is shown. The touch elements 1135 includes an I/O port 1140 coupled to the wireless antenna 1110. In some implementations, the touch elements 1135 may also include the internal antenna 1115 enclosed within the housing 150. For example, the wireless antenna 1110 may receive status information from a remote device (e.g., an edge device). For example, the touch elements 1135 may remotely control the remote device using the wireless antenna 1110.

As shown in FIG. 11F, an exemplary ICTS 1145 includes the display 1105. In this example, the display 1105 may include four 7-segment digit displays. In some implementations, other displays may be embedded in the exemplary ICTS 1145. For example, the display 1105 may include an LCD display.

Although various embodiments have been described with reference to the figures, other embodiments are possible.

In various embodiments, some bypass circuits implementations may be controlled in response to signals from analog or digital components, which may be discrete, integrated, or a combination of each. Some embodiments may include programmed, programmable devices, or some combination thereof (e.g., PLAs, PLDs, ASICs, microcontroller, microprocessor), and may include one or more data stores (e.g., cell, register, block, page) that provide single or multi-level digital data storage capability, and which may be volatile, non-volatile, or some combination thereof. Some control functions may be implemented in hardware, software, firmware, or a combination of any of them.

Computer program products may contain a set of instructions that, when executed by a processor device, cause the processor to perform prescribed functions. These functions may be performed in conjunction with controlled devices in operable communication with the processor. Computer program products, which may include software, may be stored in a data store tangibly embedded on a storage medium, such as an electronic, magnetic, or rotating storage device, and may be fixed or removable (e.g., hard disk, floppy disk, thumb drive, CD, DVD).

Although an example of a system, which may be portable, has been described with reference to the above figures, other implementations may be deployed in other processing applications, such as desktop and networked environments.

Temporary auxiliary energy inputs may be received, for example, from chargeable or single use batteries, which may enable use in portable or remote applications. Some embodiments may operate with other DC voltage sources, such as 9V batteries, for example. Alternating current (AC) inputs, which may be provided, for example from a 50/60 Hz power port, or from a portable electric generator, may be received via a rectifier and appropriate scaling. Provision for AC (e.g., sine wave, square wave, triangular wave) inputs may include a line frequency transformer to provide voltage step-up, voltage step-down, and/or isolation.

Although particular features of an architecture have been described, other features may be incorporated to improve performance. For example, caching (e.g., L1, L2, . . . ) techniques may be used. Random access memory may be included, for example, to provide scratch pad memory and or to load executable code or parameter information stored for use during runtime operations. Other hardware and software may be provided to perform operations, such as network or other communications using one or more protocols, wireless (e.g., infrared) communications, stored operational energy and power supplies (e.g., batteries), switching and/or linear power supply circuits, software maintenance (e.g., self-test, upgrades), and the like. One or more communication interfaces may be provided in support of data storage and related operations.

Some systems may be implemented as a computer system that can be used with various implementations. For example, various implementations may include digital circuitry, analog circuitry, computer hardware, firmware, software, or combinations thereof. Apparatus can be implemented in a computer program product tangibly embodied in an information carrier, e.g., in a machine-readable storage device, for execution by a programmable processor; and methods can be performed by a programmable processor executing a program of instructions to perform functions of various embodiments by operating on input data and generating an output. Various embodiments can be implemented advantageously in one or more computer programs that are executable on a programmable system including at least one programmable processor coupled to receive data and instructions from, and to transmit data and instructions to, a data storage system, at least one input device, and/or at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, which may include a single processor or one of multiple processors of any kind of computer. Generally, a processor will receive instructions and data from a read-only memory or a random-access memory or both. The essential elements of a computer are a processor for executing instructions and one or more memories for storing instructions and data. Generally, a computer will also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including, by way of example, semiconductor memory devices, such as EPROM, EEPROM, and flash memory devices; magnetic disks, such as internal hard disks and removable disks; magneto-optical disks; and CD-ROM and DVD-ROM disks. The processor and the memory can be supplemented by, or incorporated in, ASICs (application-specific integrated circuits).

In some implementations, each system may be programmed with the same or similar information and/or initialized with substantially identical information stored in volatile and/or non-volatile memory. For example, one data interface may be configured to perform auto configuration, auto download, and/or auto update functions when coupled to an appropriate host device, such as a desktop computer or a server.

In various implementations, the system may communicate using suitable communication methods, equipment, and techniques. For example, the system may communicate with compatible devices (e.g., devices capable of transferring data to and/or from the system) using point-to-point communication in which a message is transported directly from the source to the receiver over a dedicated physical link (e.g., fiber optic link, point-to-point wiring, daisy-chain). The components of the system may exchange information by any form or medium of analog or digital data communication, including packet-based messages on a communication network. Examples of communication networks include, e.g., a LAN (local area network), a WAN (wide area network), MAN (metropolitan area network), wireless and/or optical networks, the computers and networks forming the Internet, or some combination thereof. Other implementations may transport messages by broadcasting to all or substantially all devices that are coupled together by a communication network, for example, by using omni-directional radio frequency (RF) signals. Still other implementations may transport messages characterized by high directivity, such as RF signals transmitted using directional (i.e., narrow beam) antennas or infrared signals that may optionally be used with focusing optics. Still other implementations are possible using appropriate interfaces and protocols such as, by way of example and not intended to be limiting, USB 2.0, Firewire, ATA/IDE, RS-232, RS-422, RS-485, 802.11 a/b/g, Wi-Fi, Ethernet, IrDA, FDDI (fiber distributed data interface), token-ring networks, multiplexing techniques based on frequency, time, or code division, or some combination thereof. Some implementations may optionally incorporate features such as error checking and correction (ECC) for data integrity, or security measures, such as encryption (e.g., WEP) and password protection.

Various examples of modules may be implemented using circuitry, including various electronic hardware. By way of example and not limitation, the hardware may include transistors, resistors, capacitors, switches, integrated circuits, other modules, or some combination thereof. In various examples, the modules may include analog logic, digital logic, discrete components, traces and/or memory circuits fabricated on a silicon substrate including various integrated circuits (e.g., FPGAs, ASICs), or some combination thereof. In some embodiments, the module(s) may involve execution of preprogrammed instructions, software executed by a processor, or some combination thereof. For example, various modules may involve both hardware and software.

In an illustrative aspect, an inline touch input apparatus may include an input port configured to receive control signals. The inline touch input apparatus may include an output port configured to transmit output signals. The inline touch input apparatus may include a single inline circuit board extending in a horizontal axis. For example, the single inline circuit board serially and operably connecting the input port and the output port.

For example, the single inline circuit board may include a memory including a first predetermined set of rules to identify a plurality of input gestures. The single inline circuit board may include a microcontroller operably coupled to the memory configured to execute the predetermined set of rules. The single inline circuit board may include light emitting diodes (LEDs) operably coupled to the microcontroller; and at least one capacitive touch input electrode directly disposed on the single inline circuit board and operably coupled to the microcontroller; and a housing enclosing the single inline circuit board.

For example, the housing may include at least one saddle depression. For example, each of the at least one saddle depression may be configured to locate directly above a corresponding one of the at least one capacitive touch input electrode in a vertical axis. For example, the at least one saddle depression may be configured to register with the corresponding capacitive touch-input electrode.

For example, when a user places a body portion in any of the at least one saddle depression such that the body portion operably engages with the at least one capacitive touch input electrode through the housing, one of the plurality of input gestures may be identified, and the microcontroller may be configured to generate an output signal based on the identified input gesture.

For example, the microcontroller may be configured to selectively activate the LEDs. For example, the housing may include an at least partially translucent portion such that a visual indicium emitted by the LEDs may be transmitted through the housing.

For example, the housing further may include an inner mold and an outer mold. For example, the outer mold and the inner mold may include different levels of translucence. For example, the output port may be serially coupled to an input port of a downstream inline touch input apparatus. For example, the memory may include a second predetermined set of rules to identify a destination of a control signal received at the input port.

For example, when a control signal designated for the downstream inline touch input apparatus may be received at the input port, the microcontroller may be configured to generate a pass-through signal at the output port based on the second predetermined set of rules to identify the destination of the control signal.

For example, the output port may be serially coupled to an edge device. For example, the single inline circuit board may be configured to generate a control signal to remotely control the edge device. For example, the housing may be overmolded over the single inline circuit board entirely such that the single inline circuit board may be protected against water. For example, the at least one capacitive touch input electrode may include a transparent semiconductor film.

In an illustrative example, an inline touch input apparatus may include an input port configured to receive control signals. The inline touch input apparatus may include an output port configured to transmit output signals. The inline touch input apparatus may include a single inline circuit board extending in a horizontal axis. For example, the single inline circuit board may serially and operably connect the input port and the output port. For example, the inline touch input apparatus may include a housing enclosing the single inline circuit board.

For example, the single inline circuit board may include at least one capacitive touch input electrode directly disposed on the single inline circuit board. For example, the housing may include at least one saddle depression. For example, each of the at least one saddle depression may be located directly above a corresponding one of the at least one capacitive touch input electrode in a vertical axis. For example, the at least one saddle depression may be configured to register with the corresponding capacitive touch-input electrode.

For example, when a user places a body portion in any of the at least one saddle depression, the body portion may be positioned to operably engage with the at least one capacitive touch input electrode through the housing. For example, the single inline circuit board may include a memory including a first predetermined set of rules to identify a plurality of input gestures. For example, the single inline circuit board may include a control circuit operably coupled to the memory.

For example, when one of the plurality of input gestures may be received from the at least one capacitive touch input electrode, the control circuit may be configured to generate an output signal based on the first predetermined set of rules.

For example, the control circuit may include a microcontroller. For example, the single inline circuit board further may include at least one status indicator configured to emit a visual indicium. For example, the control circuit may be configured to selectively activate the at least one status indicator. For example, the housing may include an at least partially translucent portion such that the visual indicium emitted by the at least one status indicator may be transmitted through the housing.

For example, the at least one status indicator may include light emitting diodes. For example, the housing further may include an inner mold and an outer mold. For example, the outer mold and the inner mold may include different levels of translucence.

For example, the output port may be serially coupled to an input port of a downstream inline touch input apparatus. For example, the memory may include a second predetermined set of rules to identify a destination of a control signal received at the input port. For example, when a control signal designated for the downstream inline touch input apparatus may be received at the input port, the control circuit may be configured to generate a pass-through signal at the output port based on the second predetermined set of rules to identify the destination of the control signal.

For example, the output port may be serially coupled to an edge device. For example, the single inline circuit board may be configured to generate a control signal to remotely control the edge device. For example, the housing may be overmolded over the single inline circuit board entirely such that the single inline circuit board may be protected against water.

For example, the at least one capacitive touch input electrode may include a transparent semiconductor film.

In an illustrative example, an inline touch input apparatus may include an input port configured to receive control signals. The inline touch input apparatus may include an output port configured to transmit output signals. The inline touch input apparatus may include a single inline circuit board extending in a horizontal axis, serially and operably connecting the input port and the output port. The inline touch input apparatus may include a housing enclosing the single inline circuit board. For example, the single inline circuit board may include at least one capacitive touch input electrode directly disposed on the single inline circuit board. For example, the housing may include means for registering the at least one capacitive touch input electrode. For example, the means for registering the at least one capacitive touch input electrode may be configured to locate directly above a corresponding one of the at least one capacitive touch input electrode in a vertical axis. For example, when a user places a body portion in the means for registering the at least one capacitive touch input electrode, the body portion may operably engage with the at least one capacitive touch input electrode through the housing.

For example, the single inline circuit board further may include a memory including a predetermined set of rules to identify a plurality of input gestures. The single inline circuit board may include a control circuit operably coupled to the memory. For example, when one of the plurality of input gestures may be received from the at least one capacitive touch input electrode, the control circuit may be configured to generate an output signal based on the predetermined set of rules.

For example, the single inline circuit board further may include at least one status indicator configured to emit a visual indicium. For example, the control circuit may be configured to selectively activate the at least one status indicator. For example, the housing may include an at least partially translucent portion such that the visual indicium emitted by the at least one status indicator may be transmitted through the housing.

In some examples, the inline touch input apparatus of any of [0097-0113] may be combined with any of the inline touch input apparatus of any of [0114-116]. In some examples, the inline touch input apparatus of any of [0114-116] may be combined with any of the inline touch input apparatus of any of [0097-114].

A number of implementations have been described. Nevertheless, it will be understood that various modifications may be made. For example, advantageous results may be achieved if the steps of the disclosed techniques were performed in a different sequence, or if components of the disclosed systems were combined in a different manner, or if the components were supplemented with other components. Accordingly, other implementations are contemplated within the scope of the following claims.

What is claimed is:

1. An inline touch input apparatus comprising:
an input port configured to receive control signals;
an output port configured to transmit output signals;
a single inline circuit board extending in a horizontal axis, the single inline circuit board serially and operably connecting the input port and the output port, wherein the single inline circuit board comprises:
a memory comprising a first predetermined set of rules to identify a plurality of input gestures;
a microcontroller operably coupled to the memory configured to execute the first predetermined set of rules;
light emitting diodes (LEDs) operably coupled to the microcontroller; and,
at least one capacitive touch input electrode directly disposed on the single inline circuit board and operably coupled to the microcontroller; and,
a housing enclosing the single inline circuit board, wherein:
the housing comprises at least one saddle depression, wherein each of the at least one saddle depression is configured to locate directly above a corresponding one of the at least one capacitive touch input electrode in a vertical axis, wherein the at least one saddle depression is configured to register with the corresponding one of the at least one capacitive touch input electrode, such that,
when a user places a body portion in any of the at least one saddle depression such that the body portion operably engages with the at least one capacitive touch input electrode through the housing, one of the plurality of input gestures is identified, and the microcontroller is configured to generate an output signal based on the identified one of the plurality of input gestures.

2. The inline touch input apparatus of claim 1, wherein:
the microcontroller is configured to selectively activate the LEDs, and,
the housing comprises an at least partially translucent portion such that a visual indicium emitted by the LEDs is transmitted through the housing.

3. The inline touch input apparatus of claim 1, wherein the housing further comprises an inner mold and an outer mold, wherein the outer mold and the inner mold comprise different levels of translucence.

4. The inline touch input apparatus of claim 1, wherein the output port is serially coupled to a downstream inline touch input apparatus, wherein:
the memory further comprising a second predetermined set of rules to identify a destination of a control signal received at the input port, such that,
when a downstream control signal designated for the downstream inline touch input apparatus is received at the input port, the microcontroller is configured to generate a pass-through signal at the output port based on the second predetermined set of rules to identify the destination of the downstream control signal.

5. The inline touch input apparatus of claim 1, wherein the output port is serially coupled to an edge device, wherein the single inline circuit board is configured to generate a control signal to remotely control the edge device.

6. The inline touch input apparatus of claim 1, wherein the housing is overmolded over the single inline circuit board entirely such that the single inline circuit board is protected against water.

7. The inline touch input apparatus of claim 1, wherein the at least one capacitive touch input electrode comprises a transparent semiconductor film.

8. An inline touch input apparatus comprising:
an input port configured to receive control signals;
an output port configured to transmit output signals;
a single inline circuit board extending in a horizontal axis, the single inline circuit board serially and operably connecting the input port and the output port; and,
a housing enclosing the single inline circuit board, wherein:
the single inline circuit board comprises at least one capacitive touch input electrode directly disposed on the single inline circuit board, and,
the housing comprises at least one saddle depression, wherein each of the at least one saddle depression is located directly above a corresponding one of the at least one capacitive touch input electrode in a vertical axis, wherein the at least one saddle depression is configured to register with the corresponding one of the at least one capacitive touch input electrode, such that,
when a user places a body portion in any of the at least one saddle depression, the body portion is positioned to operably engage with the at least one capacitive touch input electrode through the housing.

9. The inline touch input apparatus of claim 8, wherein the single inline circuit board further comprising:
a memory comprising a first predetermined set of rules to identify a plurality of input gestures; and,
a control circuit operably coupled to the memory, wherein:
when one of the plurality of input gestures is received from the at least one capacitive touch input electrode, the control circuit is configured to generate an output signal based on the first predetermined set of rules.

10. The inline touch input apparatus of claim 9, wherein the control circuit comprises a

11. The inline touch input apparatus of claim 9, wherein the single inline circuit board further comprises at least one status indicator configured to emit a visual indicium, wherein:
the control circuit is configured to selectively activate the at least one status indicator, and,
the housing comprises an at least partially translucent portion such that the visual indicium emitted by the at least one status indicator is transmitted through the housing.

12. The inline touch input apparatus of claim 11, wherein the at least one status indicator comprises light emitting diodes.

13. The inline touch input apparatus of claim 8, wherein the housing further comprises an inner mold and an outer mold, wherein the outer mold and the inner mold comprise different levels of translucence.

14. The inline touch input apparatus of claim 9, wherein the output port is serially coupled to a downstream inline touch input apparatus, wherein:
the memory further comprising a second predetermined set of rules to identify a destination of a control signal received at the input port, such that,
when a downstream control signal designated for the downstream inline touch input apparatus is received at the input port, the control circuit is configured to generate a pass-through signal at the output port based on the second predetermined set of rules to identify the destination of the downstream control signal.

15. The inline touch input apparatus of claim 8, wherein the output port is serially coupled to an edge device, wherein the single inline circuit board is configured to generate a control signal to remotely control the edge device.

16. The inline touch input apparatus of claim 8, wherein the housing is overmolded over the single inline circuit board entirely such that the single inline circuit board is protected against water.

17. The inline touch input apparatus of claim 8, wherein the at least one capacitive touch input electrode comprises a transparent semiconductor film.

18. An inline touch input apparatus comprising:
an input port configured to receive control signals;
an output port configured to transmit output signals;
a single inline circuit board extending in a horizontal axis, serially and operably connecting the input port and the output port; and,
a housing enclosing the single inline circuit board, wherein:
the single inline circuit board comprises at least one capacitive touch input electrode directly disposed on the single inline circuit board, and,
the housing comprises means for registering the at least one capacitive touch input electrode, wherein the means for registering the at least one capacitive touch input electrode is configured to locate directly above a corresponding one of the at least one capacitive touch input electrode in a vertical axis, such that,
when a user places a body portion in the means for registering the at least one capacitive touch input electrode, the body portion operably engages with the at least one capacitive touch input electrode through the housing.

19. The inline touch input apparatus of claim 18, wherein the single inline circuit board further comprises:
a memory comprising a predetermined set of rules to identify a plurality of input gestures; and,
a control circuit operably coupled to the memory, wherein:
when one of the plurality of input gestures is received from the at least one capacitive touch input electrode, the control circuit is configured to generate an output signal based on the predetermined set of rules.

20. The inline touch input apparatus of claim 19, wherein the single inline circuit board further comprises at least one status indicator configured to emit a visual indicium, wherein:
the control circuit is configured to selectively activate the at least one status indicator, and,
the housing comprises an at least partially translucent portion such that the visual indicium emitted by the at least one status indicator is transmitted through the housing.
